(19) United States
(12) Patent Application Publication
(10) Pub. No.: US 2026/0324147 A1
(43) Pub. Date: Oct. 15, 2026

(54) OPTICAL PACKAGE STRUCTURE

(71) Applicant: LITE-ON TECHNOLOGY CORPORATION, TAIPEI CITY (TW)

(72) Inventors: CHEN-HSIU LIN, TAIPEI CITY (TW); BO-JHIH CHEN, TAIPEI CITY (TW)

(21) Appl. No.: 19/645,310

(22) Filed: Apr. 13, 2026

Related U.S. Application Data
(60) Provisional application No. 63/788,158, filed on Apr. 14, 2025.

(51) Int. Cl. H10H 20/85; H01S 5/02253; H01S 5/02315; H01S 5/028; H01S 5/183; H10H 20/84; H10H 20/855; H10H 20/857

(52) U.S. Cl. CPC H10H 20/8508; H01S 5/02253; H01S 5/02315; H01S 5/028; H01S 5/183; H10H 20/84; H10H 20/8506; H10H 20/855; H10H 20/857

(57) ABSTRACT

An optical package structure includes a substrate, a light emitter, and an optical package. The first surface of the substrate is provided with a first pad and a second pad, and the second surface of the substrate is provided with a third pad and a fourth pad. The light emitter is disposed on the first pad and electrically connected to the second pad. The optical package covers the light emitter, the first pad, and the second pad. Each of the first to fourth pads includes an inner metal layer and an outer metal layer. Each inner metal layer is connected to the substrate. Each outer metal layer is stacked on a corresponding inner metal layer and is farther from the substrate than the corresponding inner metal layer.

### CROSS-REFERENCE TO RELATED PATENT APPLICATION

This application claims the benefit of priority to the U.S. Provisional Patent Application Ser. No. 63/788,158, filed on Apr. 14, 2025, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to an optical package structure.

### BACKGROUND OF THE DISCLOSURE

As electronic products (e.g., smartphones) continue to evolve toward thinner, lighter, and more compact designs, infrared (IR) camera modules inside electronic devices have become increasingly important for applications such as night-time imaging, facial recognition (e.g., iris recognition), and depth sensing.

In the related art, an infrared light-emitting diode (IR LED) and a printed circuit board (PCB) that serves as a spacer are stacked together to form a multi-layer stacked package structure. However, a multi-material package structure makes it difficult for the overall package height to be effectively reduced. In addition, due to mismatches in the coefficients of thermal expansion (CTE) among the different materials, deformation is likely to occur under temperature variations, resulting in misalignment between the optical center of the LED and the optical axis of the lens, thereby degrading imaging quality. Furthermore, the multi-layer stacked configuration exhibits relatively high thermal resistance, making it difficult to efficiently dissipate heat generated by the LED, which in turn adversely affects luminous efficiency and device lifetime.

Therefore, how to improve structural design of the package structure and overcome the above-mentioned inadequacies has become an important issue to be addressed in the relevant art.

### SUMMARY OF THE DISCLOSURE

In response to the above-referenced technical inadequacies, the present disclosure provides an optical packaging structure to address issues of excessive package height, relatively high thermal resistance, and mismatched coefficients of thermal expansion resulting from a multi-layer stacked package structure, thereby improving luminous efficiency and reliability.

In order to solve the above-mentioned problems, one of the technical aspects adopted by the present disclosure is to provide an optical package structure. The optical package structure includes a substrate, a light emitter, and an optical package. The substrate has a first surface and a second surface opposite to each other. The substrate is provided with a first pad and a second pad on the first surface, and a third pad and a fourth pad on the second surface. The first pad is electrically connected to the third pad, and the second pad is electrically connected to the fourth pad. The light emitter is disposed on the first pad, and is electrically connected to the second pad. The optical package is disposed on the substrate and covers the light emitter, the first pad, and the second pad. Each of the first to fourth pads includes an inner layer and an outer layer. Each of the inner layers is connected to the substrate, and each of the outer layers is stacked on a corresponding one of the inner layers and is farther from the substrate than the corresponding inner layer.

Therefore, in the optical package structure provided by the present disclosure, a single substrate in combination with a dual copper bump configuration, in which each of the first to fourth pads respectively includes an inner metal layer directly contacting the substrate and an outer metal layer stacked on the corresponding inner metal layer, is utilized to replace the multi-layer PCB spacer stacking in the relevant art. As such, the optical package structure effectively reduces overall package height, lowers thermal resistance, and alleviates coefficient of thermal expansion mismatch issues, thereby improving heat dissipation efficiency and enhancing luminous performance.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of an optical package structure according to a first embodiment of the present disclosure;

FIG. 2 is another schematic perspective view of the optical package structure according to the first embodiment of the present disclosure;

FIG. 3 is a schematic cross-sectional view taken along line III-III of FIG. 1;

FIG. 4 is a schematic view of a stacking configuration of a plurality of metal portions of an outer layer;

FIG. 5 is a schematic perspective view of an optical package structure according to a second embodiment of the present disclosure;

FIG. 6 is a schematic cross-sectional view taken along line VI-VI of FIG. 5;

FIG. 7 is a schematic perspective view of an optical package structure according to a third embodiment of the present disclosure;

FIG. 8 is a schematic view of a substrate of the optical package structure according to the third embodiment of the present disclosure;

FIG. 9 is a schematic cross-sectional view taken along line IX-IX of FIG. 7; and

FIG. 10 is a schematic cross-sectional view of an optical package structure according to a fourth embodiment of the present disclosure.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

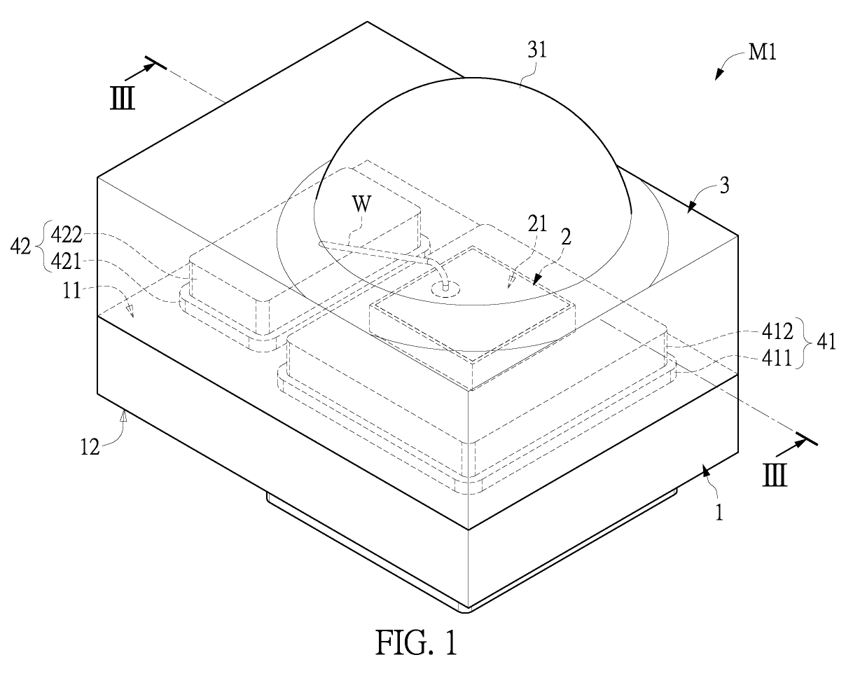

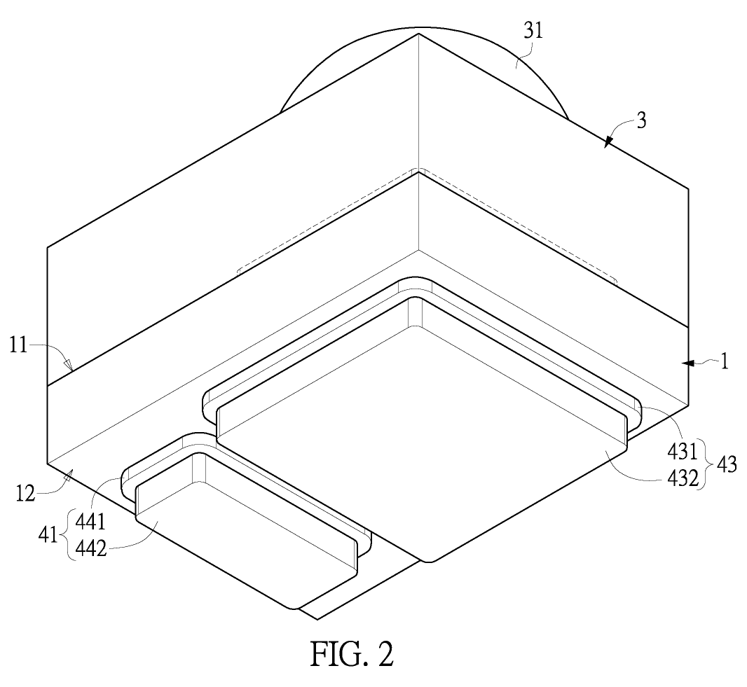

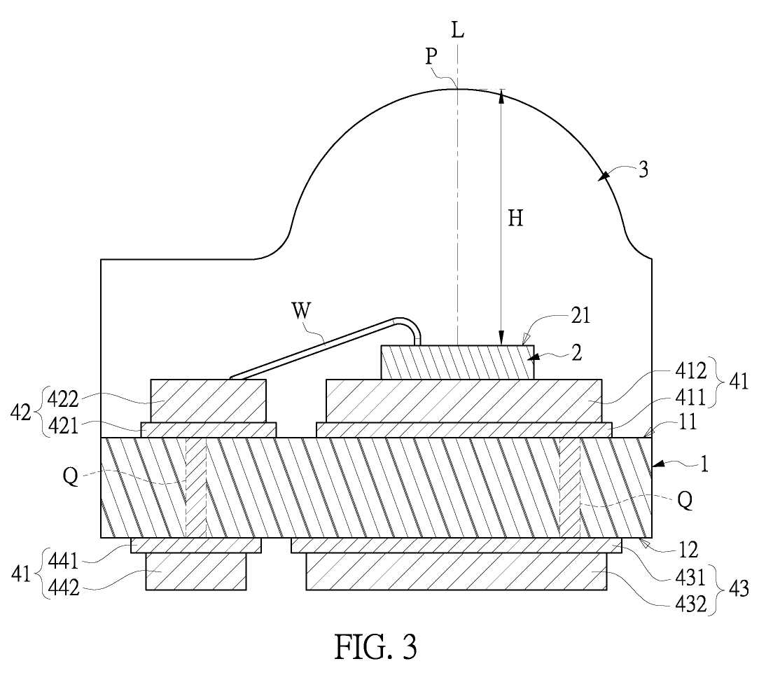

Reference is made to FIGS. 1-3. FIG. 1 is a schematic perspective view of an optical package structure according to a first embodiment of the present disclosure. FIG. 2 is another schematic perspective view of the optical package structure according to the first embodiment of the present disclosure. FIG. 3 is a schematic cross-sectional view taken along line III–III of FIG. 1. The first embodiment of the present disclosure provides an optical package structure M1, which includes a substrate 1, a light emitter 2, and an optical package 3. The substrate 1 has a first surface 11 and a second surface 12 opposite to the first surface 11. The substrate 1 is provided with a first metal pad 41 and a second metal pad 42 on the first surface 11, and a third metal pad 43 and a fourth metal pad 44 on the second surface 12. The light emitter 2 is disposed on the first metal pad 41 and is electrically connected to the second metal pad 42 through a metal wire W. The optical package 3 is disposed on the substrate 1 and covers the light emitter 2, the first metal pad 41, and the second metal pad 42.

The first metal pad 41 is electrically connected to the third metal pad 43, and the second metal pad 42 is electrically connected to the fourth metal pad 44. Regarding the electrical connection between the first metal pad 41 and the third metal pad 43, as well as between the second metal pad 42 and the fourth metal pad 44, the present disclosure is not limited thereto. As shown in FIG. 3, the electrical connection between the first metal pad 41 and the third metal pad 43, as well as between the second metal pad 42 and the fourth metal pad 44, can be achieved by conductive members Q. In one embodiment, the conductive members Q can be solid conductive copper pillars penetrating through the substrate. In another embodiment, through holes may be formed in the substrate and then filled by electroplating to form conductive vias serving as the conductive members Q.

In a preferred embodiment, the light emitter 2 can be a vertical-type infrared light-emitting diode (IR LED) chip or a vertical-cavity surface-emitting laser (VCSEL) chip. The light emitter 2 can include a first electrode, typically an N electrode, disposed on a bottom surface thereof, and a second electrode, typically a P electrode, disposed on a top surface thereof. Accordingly, the first electrode on the bottom surface of the light emitter 2 can be electrically connected directly to the first metal pad 41 by conductive adhesive or eutectic bonding, while the second electrode on the top surface of the light emitter 2 is electrically connected to the second metal pad 42 through at least one metal wire W by wire bonding, thereby completing a positive and negative electrical circuit.

A thickness of the substrate 1, defined as a distance between the first surface 11 and the second surface 12, is not less than 0.38 mm and not greater than 1 mm, and preferably is 0.5 mm. The substrate 1 is made of a high thermal conductivity insulating material, and preferably includes, but is not limited to, a ceramic substrate such as aluminum nitride or aluminum oxide, a silicon substrate, or a high thermal conductivity resin substrate. In addition, for example, the first metal pad 41, the second metal pad 42, the third metal pad 43, and the fourth metal pad 44 can be formed on the substrate 1 by direct plating copper (DPC) or direct bonded copper (DBC) processes.

Each of the first metal pad 41, the second metal pad 42, the third metal pad 43, and the fourth metal pad 44 includes an inner metal layer and an outer metal layer. The inner metal layer is connected to the substrate 1, and the outer metal layer is stacked on a corresponding inner metal layer and is farther from the substrate 1 than the corresponding inner metal layer. Specifically, the first metal pad 41 includes a first inner metal layer 411 and a first outer metal layer 412, the second metal pad 42 includes a second inner metal layer 421 and a second outer metal layer 422, the third metal pad 43 includes a third inner metal layer 431 and a third outer metal layer 432, and the fourth metal pad 44 includes a fourth inner metal layer 441 and a fourth outer metal layer 442.

Preferably, the first inner metal layer 411, the second inner metal layer 421, the third inner metal layer 431, and the fourth inner metal layer 441 have substantially equal thicknesses. It should be noted that the term “substantially equal” means that thicknesses of the metal layers are consistent with one another within allowable manufacturing tolerances. In addition, the first outer metal layer 412 and the second outer metal layer 422 have substantially equal thicknesses, and the third outer metal layer 432 and the fourth outer metal layer 442 have substantially equal thicknesses. In other words, two metal pads located on the same surface of the substrate 1 have equal thicknesses. As such, metal pads having equal thicknesses are formed on each of the first surface 11 and the second surface 12 of the substrate 1, thereby improving die bonding flatness, wire bonding reliability, molding precision of the optical package, and alignment accuracy and process yield during subsequent surface mounting technology (SMT) processes.

In one embodiment, a thickness ratio of the first inner metal layer 411 to the first outer metal layer 412 of the first metal pad 41 is 1:3. In another embodiment, a ratio of a total thickness of the first metal pad 41 to a total thickness of the third metal pad 43 ranges between 1:1 and 1.4:1, and is preferably 1.2:1. The total thickness of the first metal pad 41 is a sum of thicknesses of the first inner metal layer 411 and the first outer metal layer 412, and the total thickness of the third metal pad 43 is a sum of thicknesses of the third inner metal layer 431 and the third outer metal layer 432. By controlling thickness ratios of the metal pads on the first surface 11 and the second surface 12 of the substrate 1 within the above ranges, high correspondence of coefficients of thermal expansion on both surfaces can be achieved, thereby reducing risks of substrate warpage caused by temperature cycling during reflow soldering and cooling processes. As a result, substrate cracking, poor molding of the optical package, or optical axis deviation can be avoided, while sufficient thickness and coplanarity of solder pads on the second surface can be ensured to improve reliability and yield of subsequent surface mounting processes.

For each of the first metal pad 41, the second metal pad 42, the third metal pad 43, and the fourth metal pad 44, a projection area of the outer metal layer onto a plane of the substrate 1 is less than or equal to a projection area of the corresponding inner metal layer onto the plane of the substrate 1. More specifically, the projection of the outer metal layer onto the plane of the substrate 1 is completely located within the projection of the inner metal layer onto the plane of the substrate 1. In other words, the outer metal layer is inwardly recessed relative to the inner metal layer, thereby forming a stepped sidewall structure.

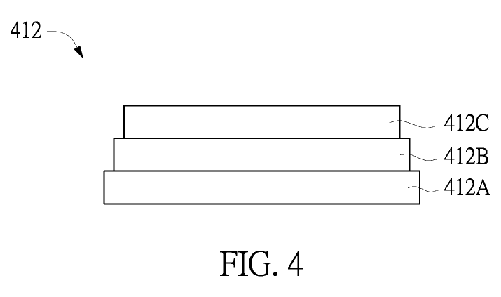

Furthermore, each outer metal layer is formed by stacking a plurality of metal portions in a layered manner. Preferably, the metal portions have substantially equal thicknesses. Referring to FIGS. 3 and 4, FIG. 4 is a schematic view of a stacking configuration of a plurality of metal portions of an outer layer. Taking the first outer metal layer 412 of the first metal pad 41 as an example, the first outer metal layer 412 is a layered structure formed by sequentially stacking a first metal portion 412A, a second metal portion 412B, and a third metal portion 412C. Each of the first metal portion 412A, the second metal portion 412B, and the third metal portion 412C has an equal thickness and is formed along a direction away from the substrate 1 by continuous electroplating. That is, the first metal portion 412A is directly stacked on the first inner metal layer 411, the second metal portion 412B is directly stacked on the first metal portion 412A, and the third metal portion 412C is directly stacked on the second metal portion 412B.

More specifically, a projection area of a metal portion disposed away from the substrate 1 onto the plane of the substrate 1 is less than or equal to a projection area of a metal portion disposed adjacent to the substrate 1. The projection of the metal portion disposed away from the substrate 1 is completely located within the projection of the metal portion disposed adjacent to the substrate 1. Taking the first outer metal layer 412 of the first metal pad 41 as an example, the projection of the second metal portion 412B is completely located within the projection of the first metal portion 412A, and the projection of the third metal portion 412C is completely located within the projection of the second metal portion 412B.

Accordingly, by providing each metal pad with a gradually inwardly recessed, stepped configuration, wherein each metal pad includes an inner metal layer and an outer metal layer, and a width of the metal pad decreases from the inner metal layer toward the outer metal layer, a more generous bonding area is effectively provided. Such a stepped structure not only tolerates alignment deviations during electrical interconnection between the inner metal layer and the outer metal layer of the same metal pad, thereby ensuring electrical stability and high manufacturing yield, but also ensures structural integrity and reliability of the package structure during subsequent manufacturing processes.

In one embodiment, the optical package 3 is made of a transparent or semi-transparent silicone or epoxy resin. As shown in FIGS. 1 and 3, a lens portion 31 is formed on the optical package 3 at a position corresponding to and directly above the light emitter 2. An outer surface of the lens portion 31 is a curved surface, and a center of curvature of the curved surface and a geometric center of a light output surface 21 of the light emitter 2 are substantially aligned on a same optical axis L. A beam angle of the lens portion 31 ranges from 60 degrees to 80 degrees. The beam angle is defined as an included angle at which light intensity is 50 percent of a maximum value. It is worth mentioning that, when the beam angle of the lens portion 31 is designed to be between 60 degrees and 80 degrees, an orthogonal spacing H between a vertex P of the curved surface and the light output surface 21 of the light emitter 2 is preferably controlled to be within a range from 1 mm to 1.5 mm.

In other words, the beam angle of the lens portion 31 can be controlled by appropriately adjusting the orthogonal spacing H between the vertex P of the curved surface and the light output surface 21 of the light emitter 2. The orthogonal spacing H exhibits a clear negative correlation with the beam angle, such that a larger spacing H corresponds to a smaller beam angle and a more concentrated light pattern. For example, when the orthogonal spacing H is 1.33 mm, the beam angle of the lens portion 31 can be 60 degrees; when the orthogonal spacing H is 1.28 mm, the beam angle can be 70 degrees; and when the orthogonal spacing H is 1.23 mm, the beam angle can be 80 degrees. Accordingly, by slightly adjusting a height of the optical package 3 to control the orthogonal spacing H within a range from 1.23 mm to 1.33 mm, a continuously adjustable beam angle from 60 degrees to 80 degrees can be achieved, thereby significantly enhancing adaptability of the optical package under different illumination scenarios while facilitating thin design of a module incorporating the optical package.

In addition, the optical package structure M1 of the present disclosure can, for example, be manufactured by the following main steps. First, laser drilling is performed on the substrate 1, such as a ceramic substrate. Then, vacuum deposition is performed on both surfaces of the substrate 1, namely the first surface 11 and the second surface 12, as well as within the drilled holes, followed by photoresist coating, exposure, and development for patterning. Subsequently, electroplating is performed to fill the holes to form conductive members Q penetrating through the substrate 1, and continuous electroplating is further performed to form the first metal pad 41, the second metal pad 42, the third metal pad 43, and the fourth metal pad 44 having a stepwise inwardly recessed structure on both surfaces (i.e., the first surface 11 and the second surface 12) of the substrate 1. After completion of the metal pad structures, surface treatments such as etching, photoresist stripping, and grinding are performed. Thereafter, the light emitter 2 is firmly bonded to the first metal pad 41 by die bonding, and electrically connected to the second metal pad 42 by the metal wire W. Then, the optical package 3 and the lens portion 31 are formed by a molding process. Finally, a singulation step is performed to complete fabrication of the optical package structure M1.

### Second Embodiment

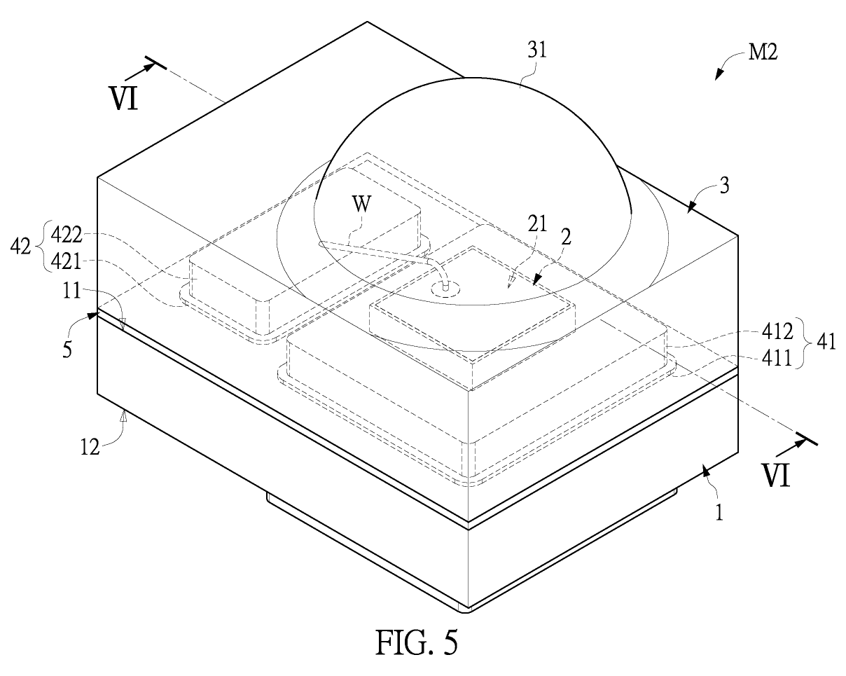

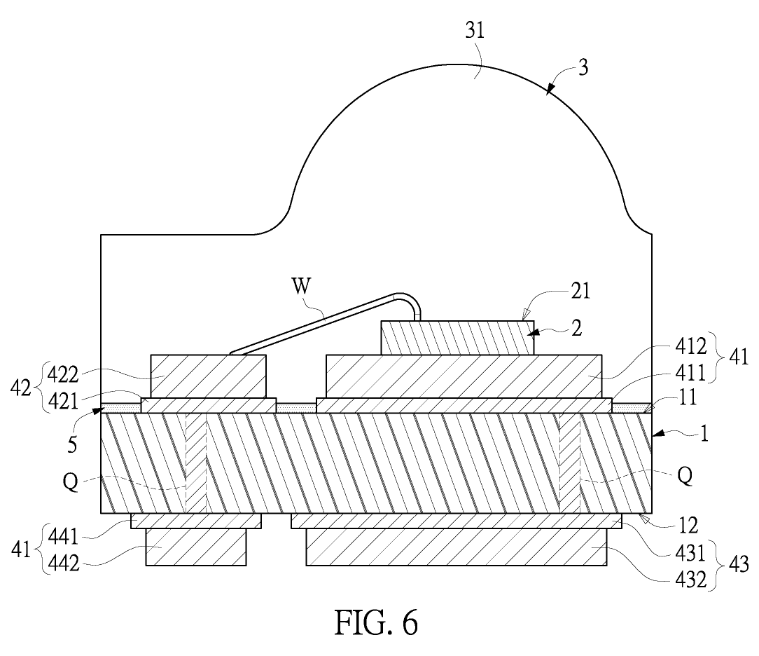

Reference is made to FIGS. 5 and 6. FIG. 5 is a schematic perspective view of an optical package structure according to a second embodiment of the present disclosure, and FIG. 6 is a schematic cross-sectional view taken along line VI-VI of FIG. 5. The second embodiment of the present disclosure provides an optical package structure M2, which includes a substrate 1, a light emitter 2, and an optical package 3 having a lens portion 31.

The substrate 1 has a first surface 11 and a second surface 12 opposite to each other. The substrate 1 is provided with a first metal pad 41 and a second metal pad 42 on the first surface 11, and is provided with a third metal pad 43 and a fourth metal pad 44 on the second surface 12. The light emitter 2 is disposed on the first metal pad 41 by die bonding, and is electrically connected to the second metal pad 42 through a metal wire W. The optical package 3 is integrally formed on the first surface 11 of the substrate 1 to completely cover the light emitter 2, the metal wire W, the first metal pad 41, and the second metal pad 42. Moreover, the optical package 3 has a lens portion 31 formed at a top thereof, and the lens portion 31 having a predetermined optical curved surface.

It should be noted that the optical package structure M2 of the second embodiment and the optical package structure M1 of the first embodiment (refer to FIGS. 1 to 4) are substantially the same in terms of the arrangement of the substrate 1 and the light emitter 2, the structures of the metal pads (i.e., the first metal pad 41, the second metal pad 42, the third metal pad 43, and the fourth metal pad 44), an overall shape of the optical package 3, and a structural design of the lens portion 31. Accordingly, the similarities will not be reiterated herein, and only distinguishing features of the second embodiment are described below.

A primary distinguishing feature of the second embodiment is as follows. The optical package structure M2 further includes a coating layer 5. For example, the coating layer 5 is a solder mask layer. The coating layer 5 selectively covers the first surface 11 of the substrate 1, and openings are locally formed in the coating layer 5 to expose the first inner metal layer 411 of the first metal pad 41 and the second inner metal layer 421 of the second metal pad 42, thereby enabling die bonding and wire bonding of the light emitter 2. Preferably, a thickness of the coating layer 5 is less than a thickness of the inner metal layer of each of the first metal pad 41 and the second metal pad 42, that is, less than a thickness of the first inner metal layer 411 and a thickness of the second inner metal layer 421. As such, a top surface of the coating layer 5 is ensured to be lower than top surfaces of the inner metal layers.

In addition, the coating layer 5 is preferably made of a black material, such as black epoxy resin, black silicone, epoxy resin containing a high concentration of carbon black, or black photoresist, and the present disclosure is not limited thereto. By selecting a black material for the coating layer 5, lateral and bottom stray light generated by the light emitter 2 can be effectively blocked, thereby preventing internal light leakage or multiple-reflection light from entering an image sensor in the same system (not shown in the figures). Moreover, abnormal phenomena such as sensing signal distortion, white balance shift, or ranging error caused by stray-light interference can be avoided, and a signal-to-noise ratio (SNR) and measurement accuracy of an overall optical system are significantly improved.

### Third Embodiment

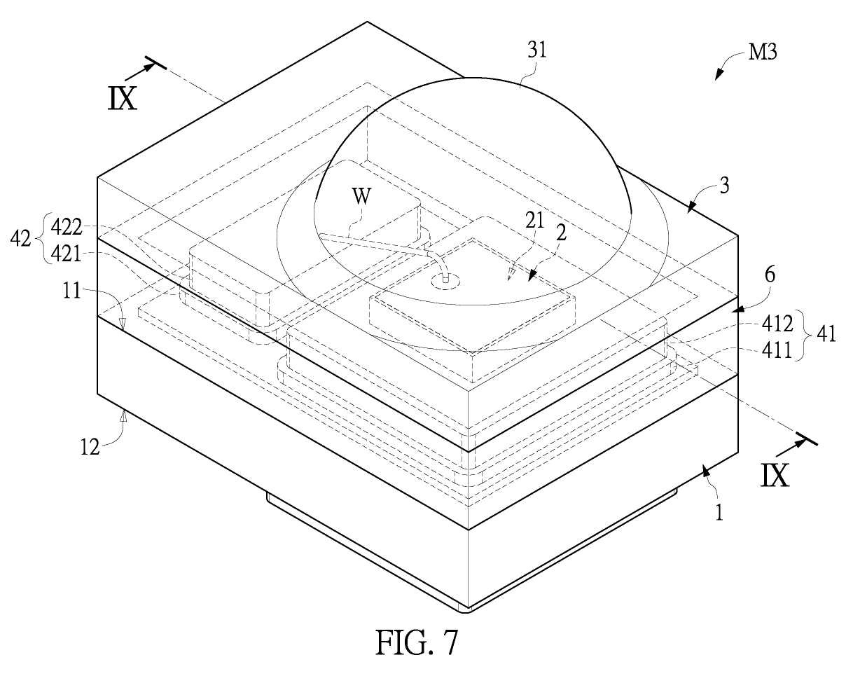

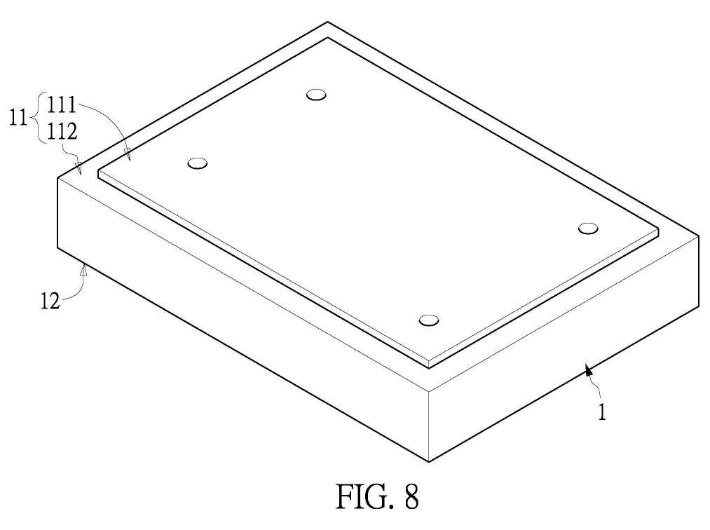

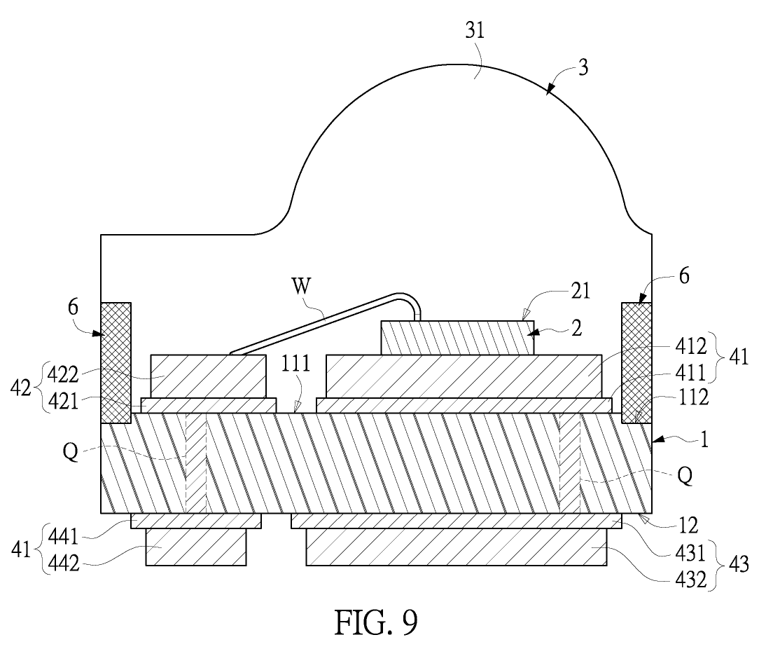

Reference is made to FIGS. 7 to 9. FIG. 7 is a schematic perspective view of an optical package structure according to a third embodiment of the present disclosure, FIG. 8 is a schematic view of a substrate of the optical package structure according to the third embodiment of the present disclosure, and FIG. 9 is a schematic cross-sectional view taken along line IX-IX of FIG. 7. The third embodiment of the present disclosure provides an optical package structure M3, which includes a substrate 1, a light emitter 2, and an optical package 3 having a lens portion 31.

The substrate 1 has a first surface 11 and a second surface 12 opposite to each other. The substrate 1 is provided with a first metal pad 41 and a second metal pad 42 on the first surface 11, and is provided with a third metal pad 43 and a fourth metal pad 44 on the second surface 12. The light emitter 2 is disposed on the first metal pad 41 by die bonding, and is electrically connected to the second metal pad 42 through a metal wire W. The optical package 3 is integrally formed on the first surface 11 of the substrate 1 to completely cover the light emitter 2, the metal wire W, the first metal pad 41, and the second metal pad 42. Moreover, the optical package 3 has a lens portion 31 formed at a top thereof, and the lens portion 31 having a predetermined optical curved surface.

It should be noted that the optical package structure M3 of the third embodiment and the optical package structure M1 of the first embodiment (refer to FIGS. 1 to 4) are substantially the same in terms of the arrangement of the substrate 1 and the light emitter 2, the structures of the metal pads (i.e., the first metal pad 41, the second metal pad 42, the third metal pad 43, and the fourth metal pad 44), an overall shape of the optical package 3, and a structural design of the lens portion 31. Accordingly, the similarities will not be reiterated herein, and only distinguishing features of the third embodiment are described below.

In the optical package structure M3 of the third embodiment, a stepped structure is further formed on the first surface 11 of the substrate 1. The stepped structure includes a first step surface 111 at a higher position and a second step surface 112 at a lower position. The second step surface 112 surrounds the first step surface 111, and the first step surface 111 and the second step surface 112 are connected to each other through a sidewall surface. The light emitter 2, the first metal pad 41, and the second metal pad 42 are all disposed on the higher first step surface 111.

The optical package structure M3 further include an annular wall 6. The annular wall 6 is vertically disposed on the second step surface 112 and surrounds the light emitter 2, the first metal pad 41, and the second metal pad 42. A portion of packaging material of the optical package 3 is formed within the annular wall 6 and covers the light emitter 2, the first metal pad 41, and the second metal pad 42, and another portion thereof covers a top surface of the annular wall 6 and extends upward to form the lens portion 31, thereby forming an integrally molded optical structure.

A light transmittance of the annular wall 6 is not greater than 10%. Preferably, the annular wall 6 is made of a black material, such as black epoxy resin, black silicone, epoxy resin containing a high concentration of carbon black, or black photoresist, and the present disclosure is not limited thereto. By selecting a black material for the annular wall 6, lateral and bottom stray light generated by the light emitter 2 can be effectively blocked, thereby preventing internal light leakage or multiple-reflection light from entering an image sensor in the same system (not shown in the figures). Moreover, abnormal phenomena such as sensing signal distortion, white balance shift, or ranging error caused by stray-light interference can be avoided, and a signal-to-noise ratio (SNR) and measurement accuracy of an overall optical system are significantly improved.

### Fourth Embodiment

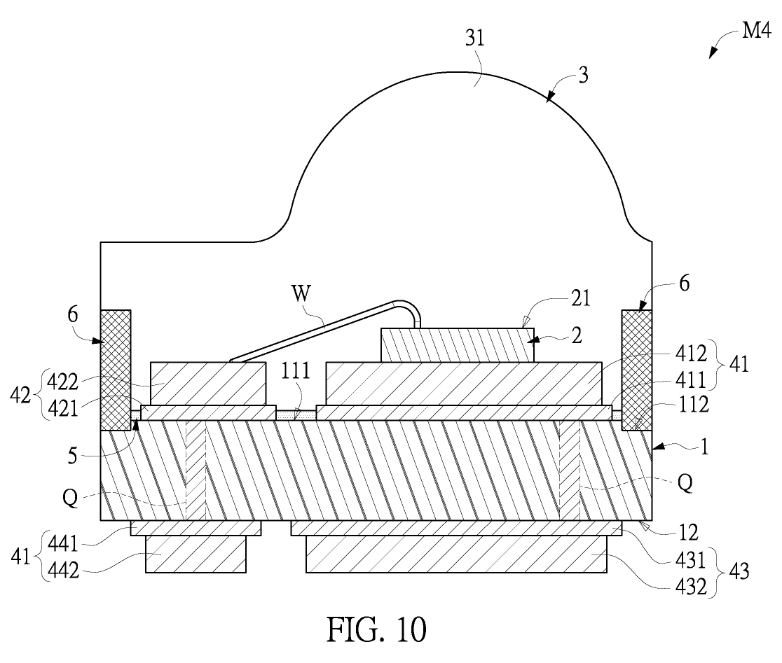

Reference is made to FIG. 10. FIG. 10 is a schematic cross-sectional view of an optical package structure according to a fourth embodiment of the present disclosure. The fourth embodiment of the present disclosure provides an optical package structure M4, which includes a substrate 1, a light emitter 2, and an optical package 3 having a lens portion 31.

The substrate 1 has a first surface 11 and a second surface 12 opposite to each other. The substrate 1 is provided with a first metal pad 41 and a second metal pad 42 on the first surface 11, and is provided with a third metal pad 43 and a fourth metal pad 44 on the second surface 12. The light emitter 2 is disposed on the first metal pad 41 by die bonding, and is electrically connected to the second metal pad 42 through a metal wire W. The optical package 3 is integrally formed on the first surface 11 of the substrate 1 to completely cover the light emitter 2, the metal wire W, the first metal pad 41, and the second metal pad 42. Moreover, the optical package 3 has a lens portion 31 formed at a top thereof, and the lens portion 31 having a predetermined optical curved surface.

The optical package structure M4 of the fourth embodiment and the optical package structure M1 of the first embodiment (refer to FIGS. 1 to 4) are substantially the same in terms of the arrangement of the substrate 1 and the light emitter 2, the structures of the metal pads (i.e., the first metal pad 41, the second metal pad 42, the third metal pad 43, and the fourth metal pad 44), an overall shape of the optical package 3, and a structural design of the lens portion 31. Accordingly, the similarities will not be reiterated herein, and only distinguishing features of the third embodiment are described below.

In the optical package structure M4 of the fourth embodiment, a stepped structure is further formed on the first surface 11 of the substrate 1. the stepped structure includes a first step surface 111 at a higher position and a second step surface 112 at a lower position. The second step surface 112 surrounds the first step surface 111, and the first step surface 111 and the second step surface 112 are connected to each other through a sidewall surface. The light emitter 2, the first metal pad 41, and the second metal pad 42 are all disposed on the higher first step surface 111.

The optical package structure M4 further include a coating layer 5 and an annular wall 6. The annular wall 6 is connected to the coating layer 5. A light transmittance of each of the coating layer 5 and the annular wall 6 is not greater than 10%, and both are preferably made of a black material. The coating layer 5 covers the first step surface 111, and openings are locally formed in the coating layer 5 to expose the first inner metal layer 411 of the first metal pad 41 and the second inner metal layer 421 of the second metal pad 42 for die bonding and wire bonding of the light emitter 2. The annular wall 6 is vertically disposed on the second step surface 112 and surrounds the coating layer 5, the light emitter 2, the first metal pad 41, and the second metal pad 42. A portion of packaging material of the optical package 3 is formed within the annular wall 6 to cover the light emitter 2, the first metal pad 41, and the second metal pad 42, and another portion thereof covers a top surface of the annular wall 6 and extends upward to form the lens portion 31, thereby forming an integrally molded optical structure.

### Beneficial Effects of the Embodiments

In conclusion, in the optical package structure provided by the present disclosure, a single substrate in combination with a dual copper bump configuration, in which each of the first to fourth pads respectively includes an inner metal layer directly contacting the substrate and an outer metal layer stacked on the corresponding inner metal layer, is utilized to replace the multi-layer PCB spacer stacking in the relevant art. As such, the optical package structure effectively reduces overall package height, lowers thermal resistance, and alleviates coefficient of thermal expansion mismatch issues, thereby improving heat dissipation efficiency and enhancing luminous performance.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An optical package structure, comprising:
a substrate having a first surface and a second surface opposite to the first surface, wherein the substrate is provided with a first pad and a second pad on the first surface, and a third pad and a fourth pad on the second surface, the first pad is electrically connected to the third pad, and the second pad is electrically connected to the fourth pad;
a light emitter disposed on the first pad, wherein the light emitter is electrically connected to the second pad; and
an optical package disposed on the substrate and covering the light emitter, the first pad, and the second pad;
wherein each of the first to fourth pads includes an inner layer and an outer layer, each of the inner layers is connected to the substrate, and each of the outer layers is stacked on a corresponding one of the inner layers and is farther from the substrate than the corresponding inner layer.

2. The optical package structure according to claim 1, wherein the inner layers of the first to fourth pads are equal in thickness.

3. The optical package structure according to claim 1, wherein the outer layer of the first pad and the outer layer of the second pad are equal in thickness, and the outer layer of the third pad and the outer layer of the fourth pad are equal in thickness.

4. The optical package structure according to claim 2, wherein a thickness ratio of the inner layer to the outer layer of the first pad is 1:3.

5. The optical package structure according to claim 1, wherein, in each of the first to fourth pads, a projection of the outer layer onto a plane of the substrate is less than or equal to a projection of the inner layer onto the plane of the substrate.

6. The optical package structure according to claim 5, wherein the projection of the outer layer onto the plane of the substrate is completely located within the projection of the inner layer onto the plane of the substrate.

7. The optical package structure according to claim 5, wherein the projection of the outer layer onto the plane of the substrate is partly located within the projection of the inner layer onto the plane of the substrate.

8. The optical package structure according to claim 1, wherein each of the outer layers includes a plurality of metal portions stacked distally from the substrate; and wherein, on a plane of the substrate, a projection area of one of the metal portions is smaller than or equal to another projection area of another one of the metal portions closer to the substrate.

9. The optical package structure according to claim 8, wherein, on the plane of the substrate, the projection of the metal portion disposed away from the substrate is completely located within the projection of the metal portion disposed adjacent to the substrate.

10. The optical package structure according to claim 8, wherein the plurality of metal portions is equal in thickness.

11. The optical package structure according to claim 1, wherein a thickness ratio of the first pad to the third pad ranges between 1:1 and 1.4:1.

12. The optical package structure according to claim 1, wherein a thickness of the substrate is not less than 0.38 mm and not greater than 1 mm.

13. The optical package structure according to claim 1, wherein the optical package body is formed with a lens portion, an outer surface of the lens portion is a curved surface, and a center of curvature of the curved surface and a geometric center of a light output surface of the light emitter are aligned on a same optical axis.

14. The optical package structure according to claim 13, wherein, when an orthogonal spacing between a vertex of the curved surface and the light output surface ranges from 1 mm to 1.5 mm, a beam angle of the lens portion ranges from 60° to 80°.

15. The optical package structure according to claim 1, further comprising a coating layer covering the first surface of the substrate and exposing the inner layer of the first pad and the inner layer of the second pad.

16. The optical package structure according to claim 15, wherein a thickness of the coating layer is less than a thickness of the inner layer of either one of the first pad and the second pad.

17. The optical package structure according to claim 1, further comprising an annular wall disposed on the first surface of the substrate and surrounding the light emitter, the first pad, and the second pad, wherein the optical package is formed within the annular wall and covers the light emitter, the first pad, and the second pad.

18. The optical package structure according to claim 15, further comprising an annular wall surrounding the coating layer, the light emitter, the first pad, and the second pad, wherein the optical package is formed within the annular wall and covers the light emitter, the first pad, and the second pad.

19. The optical package structure according to claim 18, wherein a light transmittance of each of the annular wall and the coating layer is less than or equal to 10%.

20. The optical package structure according to claim 18, wherein the annular wall is connected to the coating layer.
